(19) United States
(12) Patent Application Publication
(10) Pub. No.: US 2006/0124922 A1
(43) Pub. Date: Jun. 15, 2006

(54) Conductive ink, organic semiconductor transistor using the conductive ink, and method of fabricating the transistor

(76) Inventors: Seong Hyun Kim, Daejeon (KR); Tae Hyoung Zyung, Daejeon (KR); Jung Hun Lee, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/153,068

(22) Filed: Jun. 15, 2005

(30) Foreign Application Priority Data
Dec. 9, 2004 (KR) 2004-103688

(51) Int. Cl. H01L 29/08

(52) U.S. Cl. 257/40

(57) ABSTRACT

Provided are a conductive ink, organic semiconductor transistor using the conductive ink, and method of fabricating the transistor. The conductive ink is used to form electrodes on an organic semiconductor while minimizing the damage of the organic semiconductor. The conductive ink is formed by mixing metal nanoparticles with a conductive polymer and used as an electrode material during the fabrication of the organic semiconductor transistor using a direct printing process. By using the conductive ink as the electrode material, the production cost of the organic semiconductor transistor can be greatly reduced.

### CROSS-REFERENCE TO RELATED APPLICATION

This application claims priority to and the benefit of Korean Patent Application No. 2004-103688, filed Dec. 9, 2004, the disclosure of which is incorporated herein by reference in its entirety.

### BACKGROUND

1. Field of the Invention

The present invention relates to a conductive ink used for electrodes of an organic semiconductor thin-film transistor (OTFT) and, more specifically, to a conductive ink suitable for a direct printing process, OTFT using the conductive ink, and method of fabricating the OTFT.

2. Discussion of Related Art

Most generally, an organic field effect transistor (OFET) fabricated on an insulating substrate using an organic semiconductor thin layer is defined as an organic semiconductor thin-film transistor (OTFT). Like a field effect transistor (FET), the OTFT includes three terminals of a gate, a source, and a drain and is mainly used as a switching device. The OTFT may be applied to a sensor, a memory device, and an optical device, but is mainly utilized as a pixel switching device of an active matrix (AM) flat panel display (FPD), or as a switching device or current driving device of a liquid crystal display (LCD) or organic light emitting display (OLED).

A conventional OTFT has a horizontal structure, such as a staggered or coplanar structure. In this conventional OTFT, a source and a drain are formed using a photolithography process. In this case, it is possible to fabricate low-price OTFTs through a direct printing process.

However, the direct printing process requires a conductive ink for electrodes. Because a conventional conductive ink damages an organic semiconductor, it is necessary to develop a highly conductive ink that does not damage the organic semiconductor.

### SUMMARY OF THE INVENTION

The present invention is directed to a conductive ink, which is used to form electrodes using a direct printing process during the fabrication of an organic thin-film transistor (OTFT). Above all, even if the conductive ink is formed on an organic semiconductor thin layer, it does not damage the organic semiconductor thin layer. Also, the conductive ink has a large work function so that holes are effectively injected from the electrodes into a p-type organic semiconductor layer.

One aspect of the present invention is to provide a conductive ink, which is used in a direct printing process for forming electrodes of an organic field effect transistor (OFET), wherein the conductive ink is formed by mixing metal nanoparticles with a conductive polymer.

Another aspect of the present invention is to provide an OFET including: an organic semiconductor layer disposed on a substrate and having a source, a drain, and a channel interposed between the source and drain; a gate insulating layer disposed in contact with the channel; and a gate disposed on the substrate and separated from the channel by the gate insulating layer, wherein each of a source electrode and a drain electrode connected respectively to the source and drain is formed of the conductive ink according to the first aspect of the present invention.

Still another aspect of the present invention is to provide a method of fabricating an OFET including: forming a gate on a substrate; forming a gate insulating layer on the substrate having the gate; forming an organic semiconductor layer on the gate insulating layer, the organic semiconductor layer having a source, a drain, and a channel that is interposed between the source and drain and separated from the gate by the gate insulating layer; and forming a source electrode and a drain electrode connected to the source and drain, respectively, using the conductive ink according to the first aspect of the present invention.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a conceptual diagram of a conductive ink according to an exemplary embodiment of the present invention; and

FIG. 2 is a cross sectional view of an organic semiconductor transistor using a conductive ink according to an exemplary embodiment of the present invention.

### DETAILED DESCRIPTION OF EXEMPLARY EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art.

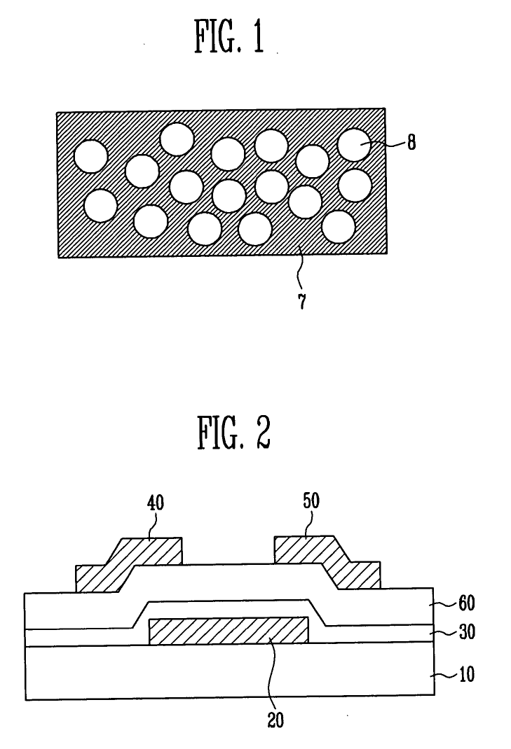

FIG. 1 is a conceptual diagram of a conductive ink according to an exemplary embodiment of the present invention.

Referring to FIG. 1, the conductive ink according to the present invention includes a conductive polymer 7 and metal nanoparticles 8. The conductive polymer 7 is highly flexible, has a large work function, and may be used as a conductive ink for a direct printing process. However, the conductive polymer 7 is even less conductive than a metal thin layer. Also, the metal nanoparticles 8 include silver (Ag) nanoparticles. The Ag nanoparticles have a small work function so that charges cannot be effectively injected into a p-type organic semiconductor layer having a large work function. Thus, the Ag nanoparticles lead to an increase in contact resistance.

For these reasons, the present invention provides a conductive ink having a high conductivity and a large work function, which is obtained by mixing the conductive polymer 7 and the metal nanoparticles 8. In the present invention, the conductive ink refers to a conductive liquid, which can be used to form metal layers for a source electrode, a drain electrode, and a gate electrode using a direct printing process during the fabrication of an OTFT.

The foregoing conductive polymer 7 includes one of polyethylene dioxythiophene polystyrene sulphonate (PEDOT:PSS), polyaniline, polypyrrole, poly(3,4-ethylenethiophene), and specific functional groups bonded thereto. A functional group refers to an element, which chemically combines with a metal to reinforce the injection of electrons or holes into the metal. For example, when thiol (—SH) radicals (not shown) are bonded to a side chain of the conductive polymer 7, the thiol (—SH) radicals are covalently bonded to gold (Au) particles, thus charges are efficiently transported between the Au particles and the conductive polymer 7. These functional groups are applied as an organic monomer type to the metal nanoparticles, and then the metal nanoparticles 8 bonded to the organic monomer are mixed with the foregoing conductive polymer 7. When a water-soluble conductive polymer, such as PEDOT:PSS, is used as the conductive polymer 7, the organic semiconductor sustains minimal damage. In addition to the water-soluble conductive polymer, the conductive polymer 7 may be other conductive polymers that are soluble in a solvent having a different property from the organic semiconductor. Likewise, the organic semiconductor sustains minimal damage.

Also, the metal nanoparticles 8 are not limited to the Ag nanoparticles, but may include other nanoparticles formed of at least one of gold (Au), copper (Cu), aluminum (Al), platinum (Pt), palladium (Pd), nickel (Ni), and chrome (Cr). Each of the metal nanoparticles 8 ranges from about 1 to 100 nm. Also, the metal nanoparticles 8 may be mixed with the conductive polymer 7 at a concentration of about 1 to 90% to achieve a high conductivity and a large work function.

In this regard, the present invention adopts the conductive polymer 7 in place of a conventional insulating resin formed of an ultraviolet (UV) curable or thermosetting material. More specifically, a conventional conductive ink contains metal nanoparticles, an UV curable resin (or a thermosetting resin), an organic solvent, a photoinitiator, and a fluid additive in an appropriate ratio. However, in the present invention, crosslinking radicals are bonded to a side chain of a conductive polymer, thereby forming crosslinking materials, which exhibit conductivity when exposed to UV rays or heat. In this process, a conductive ink having a high conductivity and a large work function can be fabricated.

FIG. 2 is a cross sectional view of an organic semiconductor transistor using a conductive ink according to an exemplary embodiment of the present invention. In FIG. 2, the organic semiconductor transistor has an inverted staggered structure.

Referring to FIG. 2, the organic semiconductor transistor includes a substrate 10, a first electrode 20, a dielectric thin layer 30, an amorphous silicon (a-Si) thin layer 60, a second electrode 40, and a third electrode 50. Here, the first electrode 20 corresponds to a gate, and the second and third electrodes 40 and 50 correspond to a source electrode and a drain electrode, respectively. Also, the dielectric thin layer 30 may be referred to a gate insulating layer, and the a-Si thin layer 60 may be referred to a semiconductor layer.

Noticeably, in the foregoing organic semiconductor transistor, the second and third electrodes 40 and 50 are formed of a conductive ink according to the present invention.

A method of fabricating the above-described organic semiconductor transistor including the source and drain electrodes formed of the conductive ink according to the present invention will now be described.

First of all, a conductive ink, which formed by mixing Ag nanoparticles of 70 nm with a predetermined amount of conductive polymer at a concentration of 30%, is prepared. Thereafter, the first electrode 20, which corresponds to the gate, is formed on the prepared substrate 10. The dielectric thin layer 30 is formed thereon.

Thereafter, the a-Si thin layer 60 is formed on the dielectric thin layer 30. Then, the conductive ink is printed using a direct printing process, thereby forming the second electrode 40 and the third electrode 50. In this case, the second and third electrodes 40 and 50, which correspond to the source and the drain, respectively, are formed apart from each other. In this process, the organic semiconductor transistor is fabricated by the direct printing process using the conductive ink according to the present invention.

The foregoing direct printing process may include at least one of an inkjet printing method, a screen printing method, a flexo printing method, a gravure printing method, an offset printing method, a pad printing method, and a printing method through a stencil.

In the meantime, although the organic semiconductor transistor having the inverted staggered structure is described in the foregoing embodiment, the present invention is not limited thereto. In other words, a variety of changes can be made to the positions and shapes of the dielectric thin layer 30, the a-Si thin layer 60, and the first through third electrodes 20, 40, and 50 of the organic semiconductor transistor according to the present invention. Accordingly, the organic semiconductor transistor according to the present invention may be variously structured such that current passes between the second and third electrodes 40 and 50, and an electric field generated by controlling a voltage applied to the first electrode 20 affects the current in a vertical direction, with the result that the organic semiconductor transistor can be switched on and off.

As described above, according to the present invention, a conductive ink having a high conductivity and a large work function can be provided to fabricate an organic semiconductor transistor using a direct printing method. Also, since electrodes of the organic semiconductor transistor are formed of an electrode material containing metal nanoparticles, the electrodes can be used as interconnections of a circuit, and charges are injected from the electrodes into organic semiconductor and effectively removed. Further, the use of the direct printing method simplifies the fabrication of the organic semiconductor transistor and greatly reduces the production cost.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. A conductive ink, which is used in a direct printing process for forming electrodes of an organic field effect transistor,
wherein the conductive ink is formed by mixing metal nanoparticles with a conductive polymer.

2. The conductive ink according to claim 1, wherein the metal nanoparticles include nanoparticles formed of at least one selected from the group consisting of silver (Ag), gold (Au), copper (Cu), aluminum (Al), platinum (Pt), palladium (Pd), nickel (Ni), and chrome (Cr).

3. The conductive ink according to claim 1, wherein the conductive polymer includes any one of polyethylene dioxythiophene polystyrene sulphonate (PEDOT:PSS), polyaniline, polypyrrole, and poly(3,4-ethylenethiophene).

4. The conductive ink according to claim 1, wherein the conductive polymer includes thiol radicals, which induce a chemical combination of the metal nanoparticles.

5. The conductive ink according to claim 1, wherein the conductive polymer includes radicals, which perform a crosslinking function under an atmosphere of one of heat and ultraviolet rays.

6. The conductive ink according to claim 1, wherein each of the metal nanoparticles ranges from about 1 to 100 nm, and each of the metal nanoparticles in the conductive polymer has a concentration of 1 to 90%.

7. An organic field effect transistor comprising:
an organic semiconductor layer disposed on a substrate and including a source, a drain, and a channel interposed between the source and drain;
a gate insulating layer disposed in contact with the channel; and
a gate disposed on the substrate and separated from the channel by the gate insulating layer,
wherein each of a source electrode and a drain electrode connected respectively to the source and drain is formed of the conductive ink according to any one of claims 1 through 6.

8. A method of fabricating an organic field effect transistor, comprising:
forming a gate on a substrate;
forming a gate insulating layer on the substrate having the gate;
forming an organic semiconductor layer on the gate insulating layer, the organic semiconductor layer having a source, a drain, and a channel that is interposed between the source and drain and separated from the gate by the gate insulating layer; and
forming a source electrode and a drain electrode connected to the source and drain respectively, using the conductive ink according to any one of claims 1 through 6.

9. The method according to claim 8, wherein forming the source and drain electrodes includes inducing a chemical combination between thiol radicals and the metal nanoparticles in order to reduce an electrical contact resistance between the metal nanoparticles and the conductive polymer.

10. The method according to claim 8, wherein forming the source and drain electrodes includes crosslinking the conductive polymer using one of ultraviolet rays and heat.

11. The method according to claim 8, wherein forming the source and drain electrodes is performed using at least one direct printing method selected from the group consisting of an inkjet printing method, a screen printing method, a flexo printing method, a gravure printing method, an offset printing method, a pad printing method, and a printing method through a stencil.
